(19) United States
(12) Patent Application Publication
(10) Pub. No.: US 2009/0084671 A1
(43) Pub. Date: Apr. 2, 2009

(54) SPUTTERING APPARATUS

(75) Inventors: Nariyoshi Hanai, Miyazaki (JP); Naoki Ichimanda, Kunitomi (JP)

Correspondence Address: MILES & STOCKBRIDGE PC, 1751 PINNACLE DRIVE, SUITE 500, MCLEAN, VA, 22102-3833, US

(73) Assignee: HITACHI PLASMA DISPLAY LIMITED

(21) Appl. No.: 12/204,018

(22) Filed: Sep. 4, 2008

(30) Foreign Application Priority Data
Oct. 2, 2007 (JP) 2007-259259

(51) Int. Cl. C23C 14/35

(52) U.S. Cl. 204/192.12

(57) ABSTRACT

A sputtering apparatus that shortens the operational down-time that accompanies target replacement is provided. The sputtering apparatus has a deposition chamber in which a sputtering target and a substrate for deposition are disposed, and includes a mobile partition that divides the deposition chamber into two spaces that are sealed off from each other by moving from a retracted position to an operational position, and undoes the dividing of the deposition chamber by moving from the operational position to the retracted position. The operational position is a position between a region in the deposition chamber in which the substrate is arranged and a region in the deposition chamber in which the sputtering target is arranged, and the apparatus is configured such that target replacement can be carried out while maintaining a vacuum state of one of the two spaces that includes the region in which the substrate is arranged.

### BACKGROUND OF THE INVENTION

1. Field of the Invention

The present invention relates to a sputtering apparatus that forms a thin film upon a substrate.

2. Description of the Related Art

A sputtering apparatus capable of performing deposition onto a large-size substrate greater than two meters on the diagonal is used in the manufacture of flat-panel displays such as plasma display panels and liquid-crystal displays. This type of sputtering apparatus is what is known as an “upright” type suited for transporting large substrates, and performs deposition onto a substrate arranged upright along the vertical direction. The sputtering target, which is the deposition material, is, like the substrate itself, arranged upright in the deposition chamber, and opposes the substrate.

Japanese Examined Patent Publication No. 6-76661 discloses an inline-type upright sputtering apparatus with improved operability during maintenance for replacing the sputtering target. In this apparatus, a sputtering cathode, which supports the sputtering target, has a door structure that opens/closes at the bottom edge of the sputtering cathode along a horizontal axis. Opening the sputtering cathode makes it possible to dispose the sputtering target horizontally. Furthermore, JP 2003-328120A discloses a sheet-type upright sputtering apparatus capable of disposing the sputtering target horizontally during target replacement.

With a conventional sputtering apparatus, although the deposition chamber can be held in a vacuum state when inserting/removing the substrate by using a load-lock system, the deposition chamber is exposed to the ambient atmosphere (in general, the atmosphere) when replacing the sputtering target. In other words, the deposition chamber is opened to the atmosphere through the opening of the abovementioned sputtering cathode. Therefore, it is necessary to clean the deposition chamber through applied heat and evacuation over a long period of time after the target has been replaced. The operating efficiency of the apparatus decreases significantly due to this cleaning.

Furthermore, it is necessary to perform deposition on a dummy substrate following the replacement in order to bring the target surface into a state suited for stable deposition. It is therefore necessary to differentiate the dummy substrate from the actual substrate onto which deposition is to be performed, and this differentiation complicates the management of the deposition process using the sputtering apparatus.

### SUMMARY

An object of the present invention is to provide a sputtering apparatus capable of shortening the operational down-time that accompanies target replacement.

Another object of the present invention is to eliminate the need for deposition onto a dummy substrate.

A sputtering apparatus that achieves the abovementioned object has a deposition chamber in which a sputtering target and a substrate for deposition are disposed, and includes a mobile partition that divides the deposition chamber into two spaces that are sealed off from each other by moving from a retracted position to an operational position, and undoes the dividing of the deposition chamber by moving from the operational position to the retracted position. The operational position is a position between a region in the deposition chamber in which the substrate is arranged and a region in the deposition chamber in which the sputtering target is arranged. With this sputtering apparatus, target replacement can be carried out while maintaining a vacuum state of one of the two spaces that includes the region in which the substrate is arranged.

Because the part of the deposition chamber divided by the partition that is exposed to the atmosphere during target replacement is limited to only one part, and thus the space that requires cleaning following the target replacement is smaller compared to the case where the entire deposition chamber is exposed. The cleaning can therefore be completed in a comparatively short amount of time. In order to shorten the time required for cleaning, it is preferable to reduce the portion of the deposition chamber that is exposed to the atmosphere. Furthermore, in order to reduce the influence of remaining impurities on the quality of the film, it is preferable for the operational position to be farther from the position in which the substrate is arranged.

In a preferred aspect of the present invention, the surface of the partition on the side of the region in which the sputtering target is arranged is composed of a material to which target particles adhere. By performing sputtering in a state where the deposition chamber is divided by the partition after target replacement, the target surface can be put into a state suited for stable deposition, without relying on deposition onto a dummy substrate.

According to the present invention, the operational down-time that accompanies target replacement can be shortened. Furthermore, a dummy substrate used for aging the sputtering target is unnecessary.

### BRIEF DESCRIPTION OF THE DRAWINGS

FIGS. 1A and 1B are schematic diagrams showing the configuration of a sputtering apparatus according to an embodiment of the present invention.

FIG. 2 is a diagram illustrating an exemplary configuration of a deposition system including a sputtering apparatus.

FIGS. 3A-3C are diagrams illustrating a function of a partition in a sputtering apparatus.

### DESCRIPTION OF THE PREFERRED EMBODIMENTS

Hereinafter, an embodiment of the present invention shall be described with reference to the drawings.

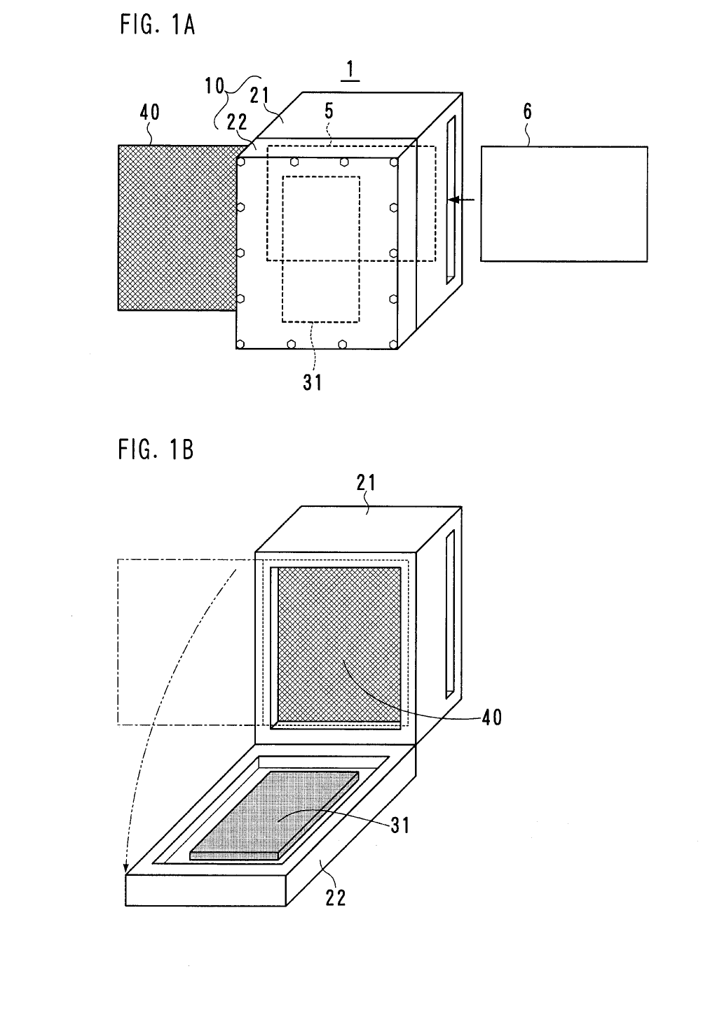

As illustrated schematically in FIGS. 1A and 1B, a sputtering apparatus 1 according to an embodiment of the present invention includes an upright-type deposition chamber device 10 into which substrates 5 and 6 that are deposition targets are inserted, in order, in an upright position or a position that is approximately upright. Substrates are unlikely to bend under their own weight when using the upright type, and thus the upright type is particularly suited for deposition onto large-sized substrates. For example, the mother substrate used in the mass-production of flat-panel displays is of a size several times larger than the screen size. The sputtering apparatus 1 shown as an example here is configured so as to be capable of deposition onto a mother substrate approximately 2 m by 1.2 m, which corresponds to three 50-inch (on the diagonal) screens' worth.

The deposition chamber device 10 is composed of a main portion 21 that houses the substrates 5 and 6 and a door portion 22 to which a sputtering target 31 is attached. The door portion 22 is configured to be pivotable around an axis running along its bottom edge, as shown in FIG. 1B. In FIG. 1A, the door portion 22 is closed, and the main portion 21 and door portion 22 fit snugly against each other via a set sealant. The door portion 22 is screwed down to the main portion 21 to increase the seal. In FIG. 1B, the door portion 22 is depicted in an opened state, and in this state the sputtering target 31 is arranged horizontally. The horizontal disposal is superior in terms of operability and safety when replacing a target through a hanging transport.

A characteristic of the sputtering apparatus 1 is that it includes a mobile partition 40 for temporarily partitioning the deposition chamber that is within the deposition chamber device 10. As shown in FIG. 1A, during deposition, the partition 40 is located in a retracted position outside of the deposition chamber. The partition 40 functions as a partition when it is located in an operational position, as shown in FIG. 1B. When the partition 40 moves from the retracted position to the operational position, it divides the deposition chamber so as to block the opening in the main portion 21 resulting from the door portion 22 opening. In other words, the deposition chamber is divided into the internal space of the main portion 21 and the space on the side of the door portion 22. Through this, the internal space of the main portion 21 can be kept in a vacuum state even when the door portion 22 is open, and the target can be replaced without opening the interior of the main portion 21 to the atmosphere.

The movement of the partition 40 is performed using a driving mechanism (not shown). The driving mechanism is configured of, for example, multiple rollers and a driving source connected to the rollers via an axial seal. The driving mechanism can also be configured of a slide guide and a pressure cylinder.

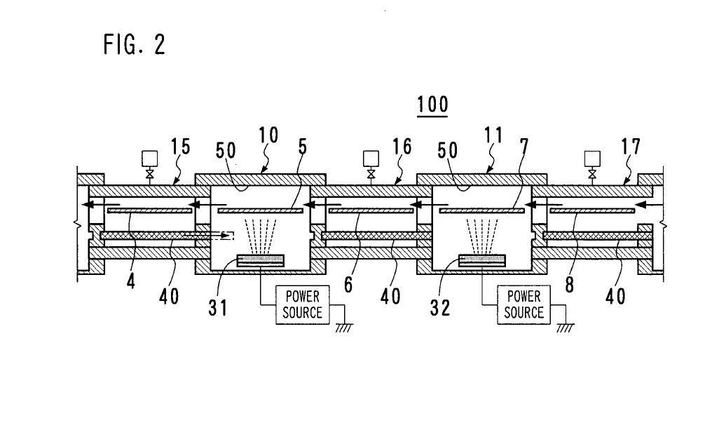

The sputtering apparatus 1 configured in as described above is incorporated into an in-line deposition system 100 as shown in FIG. 2. The deposition system 100 is configured of multiple deposition chamber devices 10 and 11 having the same configuration, connection chamber devices 15, 16, and 17, and other chamber devices, gate valves, and so on not shown in FIG. 2. Load-lock chamber devices, unload-lock chamber devices, heating chamber devices, and so on are included in the stated other chamber devices. With the deposition system 100, an evacuation system is connected to the connection chamber devices 15, 16, and 17, and deposition chambers 50 in the deposition chamber devices 10 and 11 are evacuated via the connection chamber devices 15, 16, and 17. Furthermore, the connection chamber devices 15, 16, and 17 are used in the retraction of the abovementioned partitions 40 that temporarily divide the deposition chambers 50.

Prior to deposition, the deposition chamber 50 is evacuated to approximately 10⁻⁵ Pa, after which sputtering is commenced in the deposition chamber 50 at several Pa into which a gas such as argon has been introduced. Substrates 4, 5, 6, 7, and 8 are transported from the right to the left of FIG. 2 at a constant speed of approximately 1 to 2 m per minute.

The material of the sputtering targets 31 and 32 that are arranged in the deposition chamber devices 10 and 11, respectively, and the number of deposition chamber devices 10 and 11 are selected in accordance with the composition of the film to be deposited. For example, when forming three layers, or Cr (50 nm)-Cu (3 μm)-Cr (100 nm), which are the electrodes in a plasma display panel, a total of five deposition chamber devices are connected, with one for the lower-layer Cr deposition, two for the Cu deposition, and two for the upper-layer Cr deposition. The deposition rates for the lower and upper Cr layers are the same, and the Cu deposition rate is ten times the Cr deposition rate. Through this, a desired film can be obtained through transport at a constant speed. Variations in the film thickness during mass-production can be reduced by setting the number of chamber devices in accordance with the film thickness and setting the same deposition rate for films of the same material. For example, the applied voltage may be increased/decreased in order to adjust the deposition rate.

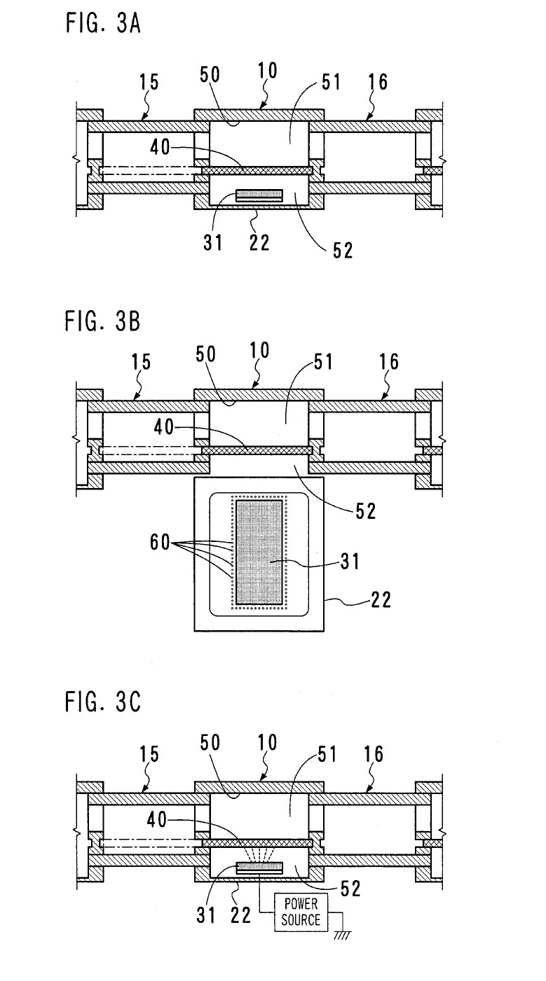

Further descriptions of the functions of the partition 40 shall be given hereinafter. The partition 40 is in the retracted position during deposition, as described above, and is arranged in the operational position prior to the door portion 22 opening for target replacement. In FIGS. 3A to 3C, the partition 40 is in the operational position. The operational position is the position between the region in the deposition chamber 50 in which the substrate is arranged and the region in the deposition chamber 50 in which the sputtering target 31 is arranged. When the partition 40 is in the operational position and the door portion 22 is closed, the deposition chamber 50 is divided into a first space 51 and a second space 52 that are sealed off from each other. The first space 51 includes the area in which the substrate is arranged, and the second space 52 includes the area in which the sputtering target 31 is arranged.

During target replacement, the second space 52 is opened to the atmosphere by operating a leak valve, after which the door portion 22 is opened as illustrated in FIG. 3B. At this time, the first space 51 is kept in a vacuum state by the partition 40. Note that gas introduction holes 60 are provided in the door portion 22 around the sputtering target 31, as shown in FIG. 3B.

The door portion 22 is closed upon the target replacement finishing, and the second space 52 can then be depressurized. The partition 40 is kept as-is and the second space 52 is evacuated to a predetermined degree, after which gas is introduced and pre-sputtering is carried out. Pre-sputtering is performed in order to age the sputtering target 31 immediately after replacement so that its surface attains a favorable condition. In order to efficiently perform pre-sputtering and reduce the load on the exhaust system, it is preferable to absorb target particles resulting from the pre-sputtering into some kind of material. The partition 40 is used as a dummy deposition surface to which the target particles adhere during pre-sputtering. For this reason, it is preferable for the surface of at least the target side of the partition 40 to be configured of a material to which target particles easily adhere. For example, a stainless-steel plate may be used as the partition 40.

The configurations of the sputtering apparatus 1 and the deposition system 100 in the above embodiment are not limited to the examples shown in the drawings. The configuration of the apparatus, including the connection location of the exhaust system, may be altered as appropriate within the scope of the present invention as long as the configuration allows the vacuum states of the first and second spaces 51 and 52 to be independently controlled. Valves may be disposed between the respective chamber devices in the deposition system 100. Furthermore, the present invention is applicable to both in-line and sheet types.

What is claimed is:

1. A sputtering apparatus having a deposition chamber in which a sputtering target and a substrate for deposition are disposed, the apparatus comprising:
a mobile partition that divides the deposition chamber into two spaces that are sealed off from each other by moving from a retracted position to an operational position, and undoes the dividing of the deposition chamber by moving from the operational position to the retracted position,
wherein the operational position is a position between a region in the deposition chamber in which the substrate is arranged and a region in the deposition chamber in which the sputtering target is arranged; and
the apparatus is configured such that target replacement can be carried out while maintaining a vacuum state of one of the two spaces that includes the region in which the substrate is arranged.

2. The sputtering apparatus according to claim 1,
wherein a surface of the partition on the side of the region in which the sputtering target is arranged is composed of a material to which target particles adhere.

3. The sputtering apparatus according to claim 1,
wherein the substrate is a mother substrate of a flat-panel display.

4. The sputtering apparatus according to claim 2,
wherein the substrate is a mother substrate of a flat-panel display.
